(19) United States
(12) Patent Application Publication
(10) Pub. No.: US 2015/0116914 A1
(43) Pub. Date: Apr. 30, 2015

(54) REMOTE CONTROL ATTACHABLE TO SURFACE OF METAL SHELL AND AN ELECTRIC APPLIANCE WITH SUCH REMOTE CONTROL

(71) Applicant: Ningbo SMAL Electrics Co., Ltd., Zhejiang (CN)

(72) Inventors: Yuejun DONG, Zhejiang (CN); Yingli YU, Zhejiang (CN)

(73) Assignee: Ningbo SMAL Electrics Co., Ltd., Zhejiang (CN)

(21) Appl. No.: 14/150,176

(22) Filed: Jan. 8, 2014

(30) Foreign Application Priority Data
Oct. 29, 2013 (CN) 201320674757X

(51) Int. Cl. H05K 5/02; H05K 5/00

(52) U.S. Cl. CPC H05K 5/02; H05K 5/0017
USPC 361/679.01; 206/525

(57) ABSTRACT

The present disclosure discloses a remote control attachable to a surface of a metal shell. The remote control comprises a shell, a remote panel provided on a front face of the shell, and a magnet built-in inside the shell. The remote control according to the present disclosure can avoid being lost easily due to no fixed position to be placed and can increase the user's convenience.

### TECHNICAL FIELD

The present disclosure relates to a remote control, and particularly to a remote control attachable to a surface of a metal shell and an electric appliance with such remote control.

### BACKGROUND ART

In the prior art, many electric appliances are equipped with remote controls to greatly increase convenience of using the electric appliances.

However, during use of the remote control, the electric appliance matched with the remote control has neither a space for receiving the remote control, nor a position for fixing the remote control; furthermore, after use, some careless users randomly place the remote control anywhere such as tea table, sofa armrest, desk or other places. Since the furniture is not provided with a special position for the remote control, the remote control is frequently moved again in clearing up of the furniture. So, the remote control may not be found when it is required, which adversely affects the use.

Therefore, it is required to design a remote control which can be put in a proper place when the user does not use it, and can be easily found when the user needs to use it, so as to ensure the user's convenience.

### SUMMARY OF THE DISCLOSURE

To overcome the problem in the prior art, one object of the present invention is to provide a remote control attachable to a surface of a metal shell, so as to solve the technical problem that the existing remote control has not a fixedly-placed position, which affect the user's convenience.

Another object of the present disclosure is to provide an electric appliance having a remote control attachable to a surface of a metal shell.

The object is achieved through following technical solutions.

In one aspect, the disclosure provides a remote control attachable to a surface of a metal shell, comprising the shell, a remote panel provided on a front face of the shell, and a magnet built-in inside the shell.

According to the remote control attachable to the surface of the metal shell of the present disclosure, in one embodiment, the magnet may be a ferromagnet.

According to the remote control attachable to the surface of the metal shell of the present disclosure, in another embodiment, the magnet may be made up of two parts distributed uniformly in a longitudinal direction of the shell.

According to the remote control attachable to the surface of the metal shell of the present disclosure, in further another embodiment, the magnet may be detachably built-in inside the shell.

According to the remote control attachable to the surface of the metal shell of the present disclosure, in still another embodiment, a back face of the shell may be provided with a receiving slot for receiving the magnet and a cover plate for covering the receiving slot.

According to the remote control attachable to the surface of the metal shell of the present disclosure, in still further another embodiment, the magnet may be provided in plurality.

In another aspect, a technical solution according to the present disclosure may be provided below.

There is provided a remote control attachable to a surface of a metal shell, comprising the shell, a remote panel provided on a front face of the shell, and a receiving slot provided with a cover plate, wherein the receiving slot is provided on a back face of the shell for receiving a magnet.

There is still provided an electric appliance, comprising a remote control attachable to a surface of a metal shell according to the present disclosure.

In one embodiment, the electric appliance according to the present disclosure may be a home heater, a television or an air conditioner.

In another embodiment, a panel or a portion of a panel of the electric appliance according to the present disclosure may be made of iron, cobalt or nickel.

In conclusion, the present disclosure may bring one or more advantageous effects as follows: because a built-in magnet is provided, the remote control attachable to the surface of the metal shell can be attached to a metal (such as, iron, cobalt or nickel) surface so as to avoid being lost due to no fixed position to be placed, and thusly increase the user's convenience.

### BRIEF DESCRIPTION OF THE DRAWINGS

FIG. 1 is a schematic view of a remote control attachable to a surface of a metal shell according to the first embodiment of the present disclosure;

FIG. 2 is a schematic view of a remote control attachable to a surface of a metal shell according to the second embodiment of the present disclosure; and

FIG. 3 is a schematic view of an electric appliance according to the present disclosure.

### DETAILED DESCRIPTION OF THE PREFERRED EMBODIMENTS

Hereinafter, the preferable embodiments including features and advantages of the present disclosure will be illustrated in details. It should be understood that variations can be made in different embodiments without departing from the spirit or scope of the present disclosure, and the description and drawings are substantially exemplary but not be construed as limiting the present disclosure.

The present disclosure provides a remote control attachable to a surface of a metal shell, which may be but not limit to a remote control of a home heater, an air cleaner, an air conditioner and a television, etc. The present disclosure also provides an electric appliance having a remote control attachable to a surface of a metal shell according to the disclosure. The present disclosure still provides an electric appliance, which may be but not limit to for example a home heater, an air cleaner, an air conditioner, a television and the like.

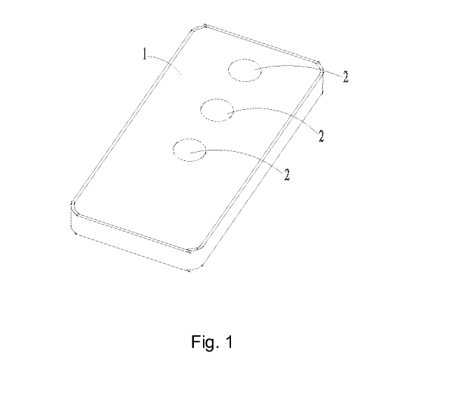

As shown in FIG. 1, the remote control attachable to the surface of the metal shell according to the first embodiment of the present disclosure may comprise a shell 1, a remote panel (not shown) and a magnet 2. The remote panel is provided on a front face of the shell 1, and the magnet 2 is built-in inside the shell 1 at a position which may be adjacent to a back face of the shell 1. The magnet 2 is for example a ferromagnet, and can be attached to the metal surface such as an iron surface, a cobalt surface, a nickel surface and so forth. The magnet 2, for example, may be a small button-shaped magnet. In addition, both the shell 1 and the remote panel may be the same as the shell and remote panel of the remote control in the prior art.

A space for the built-in magnet 2 may be formed when molding of the shell 1.

As shown in FIG. 1, the remote control attachable to the surface of the metal shell according to the first embodiment of the present disclosure may be provided with three magnets 2. The magnets 2 may be disposed in longitudinally upper position in a middle portion of the remote control, so that the remote control can be attached to the metal surface of the electric appliance remote-controlled by it when the remote control is in a non-use state, and thusly the remote control can be found whenever to be used. In the present disclosure, the number of the magnets 2 is not limited to three, that is, one, two or at least four magnets may be provided in the remote control.

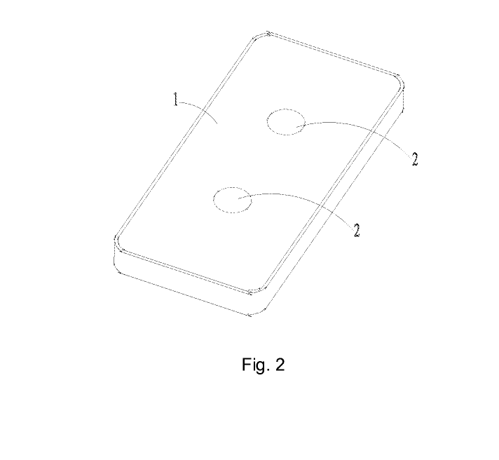

As shown in FIG. 2, in a remote control attachable to a surface of a metal shell according to the second embodiment of the present disclosure, a magnet 2 is made up of two parts distributed uniformly in the longitudinal direction of a shell 1, in other words, two magnets 2 are provided at positions of ⅓ and a ⅔ of a total length of the shell 1 in a longitudinal direction, respectively.

In addition to the measure of building the magnet 2 in the shell 1 by a non-detachable way, in the remote control attachable to the surface of the metal shell according to the present disclosure, the magnet 2 may be designed to build-in inside the shell 1 by a detachable way. Just like batteries detachably mounted in the conventional remote control, the back face of the shell 1 may be provided with a receiving slot for receiving the magnet 2 and a cover plate for covering the receiving slot. It is convenient for the user to change the magnet or take the magnet out if he feels inconvenience for magnetism of the remote control, so as to increase the user's selections. Meanwhile, the remote control attachable to the surface of the metal shell according to the present disclosure may have no magnet built-in previously, but be provided with the receiving slot for receiving the magnet and the cover plate for covering the receiving slot. If the user wants the remote control to have magnetism, he/she could have the magnet build in the receiving slot as desired. The receiving slot may be provided in plurality, e.g., one, two, three, or even more.

Hereinafter, an electric appliance of the present disclosure will be described by taking a home heater as an example.

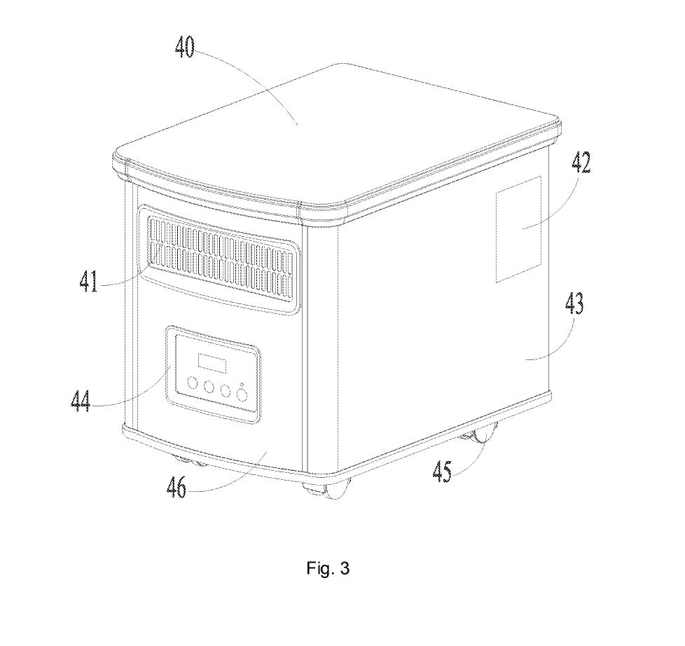

As shown in FIG. 3, an electric appliance of the present disclosure may be a home heater which has a top face 40, a front panel 46, a side panel 43, a back plate (not shown) and rollers 45. The top face 40 may be designed like a top surface of a bedside table. The front panel 46 is provided with an air outlet 41 and a control panel 44 having control keys and an indicating lamp. And rollers 45 are arranged such that the home heater can be easily moved.

For conveniently placing the remote control, a panel, e.g., the side panel 43 of the home heater may be made of iron, cobalt or nickel, or a portion of the side panel 43 may be made of iron, cobalt or nickel. Thereby, the remote control, when not used, can be attached to the side panel 43 or a portion 42 of the side panel 43 for convenient use next time.

The technical solution of the present disclosure has been disclosed in alternative embodiments as above mentioned. For those skilled in the art, it should be understood that all modifications and variations fall within the protection scope of the claims of the present disclosure without departing from the scope or spirit as defined by the appended claims of the present disclosure.

What is claimed is:

1. A remote control attachable to a surface of a metal shell, comprising:
a shell;
a remote panel provided on a front face of the shell; and
a magnet built-in inside the shell.

2. The remote control attachable to the surface of the metal shell according to claim 1, wherein the magnet is a ferromagnet.

3. The remote control attachable to the surface of the metal shell according to claim 2, wherein the magnet is made up of two parts distributed uniformly in a longitudinal direction of the shell.

4. The remote control attachable to the surface of the metal shell according to claim 1, wherein the magnet is detachably built-in inside the shell.

5. The remote control attachable to the surface of the metal shell according to claim 4, wherein a back face of the shell is provided with a receiving slot for receiving the magnet and a cover plate for covering the receiving slot.

6. The remote control attachable to the surface of the metal shell according to claim 2, wherein the magnet is provided in plurality.

7. A remote control attachable to a surface of a metal shell, comprising:
a shell;
a remote panel provided on a front face of the shell; and
a receiving slot provided with a cover plate, located on a back face of the shell for receiving a magnet.

8. An electric appliance, comprising a remote control attachable to a surface of a metal shell according to claim 1.

9. The electric appliance according to claim 8, wherein the electric appliance is a home heater, a television or an air conditioner.

10. The electric appliance according to claim 9, wherein a panel or a portion thereof of the electric appliance is made of iron, cobalt or nickel.

11. An electric appliance, comprising a remote control attachable to a surface of a metal shell according to claim 7.

12. The electric appliance according to claim 11, wherein the electric appliance is a home heater, a television or an air conditioner.

13. The electric appliance according to claim 12, wherein a panel or a portion thereof of the electric appliance is made of iron, cobalt or nickel.
